(19) United States
(12) Patent Application Publication
(10) Pub. No.: US 2007/0241828 A1
(43) Pub. Date: Oct. 18, 2007

(54) Dual mode quartz oscillation circuit

(75) Inventors: Akihiro Nakamura, Sayama-shi (JP); Minoru Fukuda, Sayama-shi (JP)

Correspondence Address: SCHWEGMAN, LUNDBERG & WOESSNER, P.A., P.O. BOX 2938, MINNEAPOLIS, MN, 55402, US

(73) Assignee: NIHON DEMPA KOGYO CO., LTD.

(21) Appl. No.: 11/726,167

(22) Filed: Mar. 21, 2007

(30) Foreign Application Priority Data
Mar. 31, 2006 (JP) 2006-101009

(51) Int. Cl. H03B 5/32

(52) U.S. Cl. 331/158

(57) ABSTRACT

Provided is a dual mode quartz oscillator capable of suppressing a B mode interference securely and also accomplishing a stable third and fifth overtone oscillations. A dual mode quartz oscillation circuit, including a first oscillation unit for oscillating a third order overtone oscillation against a fundamental wave oscillation of a quartz oscillator; a second oscillation unit for oscillating a fifth order overtone oscillation against a fundamental wave oscillation of the quartz oscillator; and a band restriction unit for inhibiting an interference of the fifth overtone oscillation between the quartz oscillator and either one of the first or second oscillation unit.

### RELATED APPLICATION

This application claims priority under 35 U.S.C. 119 to Japanese Application No. 2006-101009, filed Mar. 31, 2006, which application is incorporated herein by reference and made a part hereof.

### BACKGROUND OF THE INVENTION

1. Field of the Invention

The present invention relates to an oscillator using a quartz oscillator and in particular to a dual mode quartz oscillator performing C mode and B mode oscillations in a high stability.

2. Description of the Related Art

An SC-cut quartz oscillator is in the spotlight as a quartz oscillator in recent years. The SC-cut quartz oscillator provides a higher Q value as compared to an AT-cut quartz oscillator and has a good thermal shock characteristic, showing a good stability against a rapid temperature change. It particularly has a favorable characteristic when using it in an environment with a drastic change in temperature. A piezoelectric crystallization generally allows an excitation of piezoelectric oscillation in a specific cutting angle relative to the crystal axis. A quartz oscillator utilizing a piezoelectric characteristic of a quartz for example takes on an inherent oscillation characteristic in a specific cutting angle relative to the crystal axis.

The SC-cut quartz oscillator for example generates a B mode oscillation in the neighborhood of a C mode oscillation and also on the higher frequency side. Known is a dual mode quartz oscillator using such an SC-cut quartz oscillator and oscillating in the C mode and B mode.

Here, a value of a crystal impedance (abbreviated as “CI” hereinafter) of the B mode oscillation is equal to, or possibly smaller than, a CI of the C mode. There is accordingly a problem of an actually produced oscillator sometimes oscillating in the B mode.

Therefore, when using an SC-cut quartz oscillator, it is necessary to make the CI of the B mode larger than that of the C mode by suppressing a B mode oscillation in order to excite the C mode oscillation securely. The B mode oscillation is suppressed by a various devising such as an external form of a quartz chip, holding position thereof, et cetera.

Even with the above described devising, however, there is a problem of a sudden, large fluctuation of frequency, that is, a jump phenomenon, occurring as a result of the C mode and B mode being combined. There is a problem in which the occurrence of the jump phenomenon makes it difficult to implement a stable oscillation of both modes. There is yet another problem of being difficult to select an oscillation frequency if order numbers are the same against the basic oscillation frequency because the oscillation frequencies of the C and B modes are close to each other.

FIG. 1 is a diagram showing a dual mode quartz oscillation circuit 1-1 using a modified Colpitts circuit using an SC-cut quartz oscillator 6 (named as “quartz oscillator 6” hereinafter) as the above described conventional dual mode oscillator circuit.

The dual mode quartz oscillation circuit 1-1 is constituted by a C mode oscillation circuit unit 2-1 and a B mode oscillation circuit unit 3-1.

In the C mode oscillation circuit unit 2-1, the base of an oscillation amplification-use transistor Tr4-1 is connected to one end of a capacitor C5 and the other end thereof is connected to one end of a quartz oscillator 6. The other end of the quartz oscillator 6 is connected to one end of a capacitor C7. A serial circuit of division capacitors Ca and Cb is connected between the base and ground of the transistor Tr4-1, and a band restriction element, e.g., an LC serial circuit 9-1, is inserted between the connection point (i.e., the division point) of the division capacitors Ca and Cb.

The transistor Tr4-1, division capacitors Ca and Cb, i.e., capacitive reactance, and quartz oscillator 6, i.e., inductive reactance, constitute a Colpitts type oscillation circuit. And an oscillation wave of an oscillation frequency based on the resonance frequency of the quartz oscillator 6 is output from the collector terminal of the transistor Tr4-1 and an oscillation signal (i.e., an oscillation wave) is output to an output terminal V_{OC}.

Furthermore, the LC serial circuit 9-1 is a modified Colpitts type oscillation circuit connected to the division point.

The LC serial circuit 9-1 is for obtaining a negative resistance of a narrow band by the third order overtone of the C mode.

A variable capacity diode D8 is given a reverse bias voltage to change the capacity and change a load capacity for the quartz oscillator 6, thereby adjusting the oscillation frequency.

In the B mode oscillation circuit unit 3-1, the base of an oscillation amplification-use transistor Tr4-2 is connected to one end of a capacitor C14, and the other end thereof is connected to one end of a quartz oscillator 6. The other end of the quartz oscillator 6 is connected to one end of a capacitor C7. A serial circuit of division capacitors Cd and Ce is connected between the base and ground of the transistor Tr4-2, and a band restriction element, e.g., an LC serial circuit 9-2, is connected between the connection point (i.e., the division point) of the division capacitors Cd and Ce and the emitter of the transistor Tr4-2.

The transistor Tr4-2, division capacitors Cd and Ce, i.e., capacitive reactance, and quartz oscillator 6, i.e., inductive reactance, constitute a Colpitts type oscillation circuit. And an oscillation wave of an oscillation frequency based on the resonance frequency of the quartz oscillator 6 is output from the collector terminal of the transistor Tr4-2 and an oscillation signal (i.e., anoscillationwave) is output to an output terminal V_{OB}. Furthermore, it is a modified Colpitts type oscillation circuit to which the LC serial circuit 9-2 is connected to the division point. And the LC serial circuit 9-2 is for obtaining a negative resistance of a narrow band by the fifth order overtone of the B mode.

The dual mode quartz oscillation circuit 1-1 configured as described above provides a possibility of implementing oscillation of both modes if a part indicating characteristic of a negative resistance is obtained in the oscillation frequency bands of the C mode and B mode.

Here, FIG. 2 shows a negative resistance curve by a simulation of the dual mode quartz oscillation circuit 1-1. The vertical axis indicates resistance component “Q”, and the horizontal axis indicates frequency “MHz”. The measurement point is the “T” shown in FIG. 1.

The negative resistance is measured in the state of the quartz oscillator being disconnected from a circuit. A current source and a current meter is inserted into the place where the quartz oscillator is disconnected, and the negative resistance is calculated with the definition of V2: a voltage on the oscillation circuit side at the time, V1: a voltage on the original quarts oscillator side (i.e., the side of the variable capacitance diode being connected), and I_probe 1.i: a value of the current meter at the time; and that is, to calculate NegR=real(V2−V1)/I_probe 1.i, where “real” represents a real part.

Based on FIG. 2, a negative resistance component appears in the respective oscillation frequency bands of the C mode and of B mode. That is, the negative resistance constitutes a resistance of the real part of (V₂−V₁)/i. This shows respective oscillation points of which ml is the C mode and a frequency of 10.000 MHz with the negative resistance of −161.937 ohms; and m2 is the B mode and a frequency of 18.20 MHz with the negative resistance of −39.145 ohms.

The dual mode quartz oscillation circuit 1-1 according to the conventional example shown in FIG. 1 allows an existence of the negative resistance in two places and allows an existence of positive area (approximately 30 ohms at the maximum value) indicated by the range A between the two frequencies. This allows an occurrence of a frequency jump and that of pull-in effect of the C mode oscillation and B mode oscillation, negating an accomplishment of a stable dual mode oscillation.

According to a non-patent reference document 1, Colpitts type quartz oscillation circuits attached with an LC serial filter are connected on the left and right for oscillating in the B mode and C mode respectively. In order to suppress an influence of the left and right circuit against each other, LC serial filters of which the resonance frequency is 46 MHz (that is the third order overtone on the B mode side) and 8.3 MHz (that is the fifth order overtone on the C mode side) are attached to the connection point of the left and right circuits.

The above described conventional technique, however, has a shortfall of a limited usage because the oscillation frequency of the C mode is the fifth overtone of the fundamental wave oscillation of the quartz oscillator as opposed to the oscillation frequency of the B mode being the third overtone of the fundamental wave oscillation of the quartz oscillator.

Non-patent document 1: ENOMOTO, Shigeru; JAN, Joge; TAKENO, Nobuo; OTSUKA, Hideo; and SEKINE, Yoshifumi, “A dual mode quartz oscillator using overtones of C mode and B mode with different orders”; Nihon University Academic Lecture Presentation

### SUMMARY OF THE INVENTION

In consideration of the above described situation, the present invention aims at providing a dual mode quartz oscillation circuit using an oscillation circuit of a quartz oscillator of which an oscillation frequency of the B mode is the fifth overtone of the fundamental wave oscillation of the quartz oscillator and that of the C mode is the third overtone of the fundamental wave oscillation of the quartz oscillator and which suppresses an interference of the B mode securely.

According to one aspect of the present invention for solving the problem described above, a dual mode quartz oscillation circuit comprises: a first oscillation unit for oscillating a first mode overtone of a quartz oscillator; a second oscillation unit for oscillating a second mode overtone of the quartz oscillator; and a band restriction unit for inhibiting an interference of the overtones between the quartz oscillator and either one of the first or second oscillation unit.

This configuration is capable of a highly stable dual mode quartz oscillator.

According to the second aspect of the present invention, the dual mode quartz oscillation circuit as noted in claim 1 is configured in a manner that the first mode is the third order overtone oscillation of a C mode, and the second mode is the fifth order overtone oscillation of a B mode.

This configuration enables a stable oscillation of the third overtone and fifth overtone of the C mode and B mode, respectively.

The dual mode quartz oscillator according to the present invention is contrived to enable a stable implementation of the C mode and B mode oscillations in different orders, respectively, against the fundamental wave oscillation of a quartz oscillator.

### BRIEF DESCRIPTION OF THE DRAWINGS

FIG. 1 is a diagram showing a conventional dual mode quartz oscillation circuit using a modified Colpitts circuit using an SC-cut quartz oscillator;

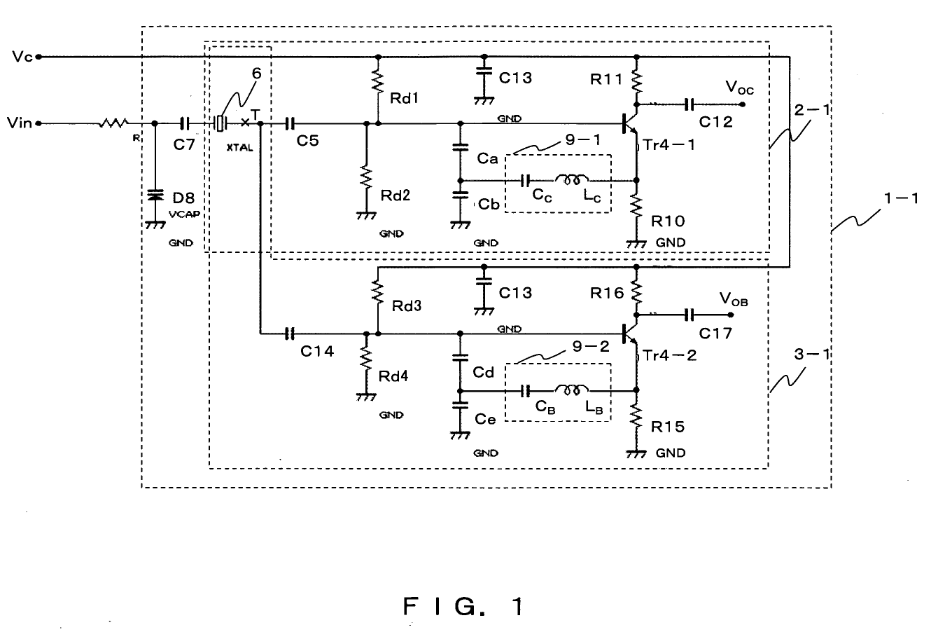

FIG. 2 is a diagram showing a negative resistance curve according to the above described conventional circuit;

FIG. 3 is a diagram showing a dual mode quartz oscillation circuit using an SC-cut quartz oscillator in a modified Colpitts type oscillation circuit according to a first embodiment of the present invention;

FIG. 4 is a diagram showing a negative resistance curve according to a first embodiment of the present invention;

FIG. 5 is a diagram showing a negative resistance curve when varying a capacitance value of a Cc of an LC serial circuit in an oscillation circuit part of a mode according to a first embodiment of the present invention;

FIG. 6 is a diagram showing a negative resistance curve when varying a capacitance value of a C_{B} of an LC serial circuit in an oscillation circuit part of a B mode according to a first embodiment of the present invention;

FIG. 7 is a diagram showing a negative resistance curve when varying a capacitance value of a Cc′ of an interference restriction-use LC serial circuit in an oscillation circuit part of a C mode in a first embodiment of the present invention;

FIG. 8 is a diagram showing a dual mode quartz oscillation circuit using an SC-cut quartz oscillator in a modified Colpitts type oscillation circuit according to a second embodiment of the present invention; and

FIG. 9 is a diagram showing a negative resistance curve when varying a capacitance value of a Cc′ of an interference restriction-use LC serial circuit in an oscillation circuit part of a B mode in a second embodiment of the present invention.

### DESCRIPTION OF THE PREFERRED EMBODIMENTS

The following is a description of the preferred embodiment of the present invention by referring to the accompanying drawings.

### First Embodiment

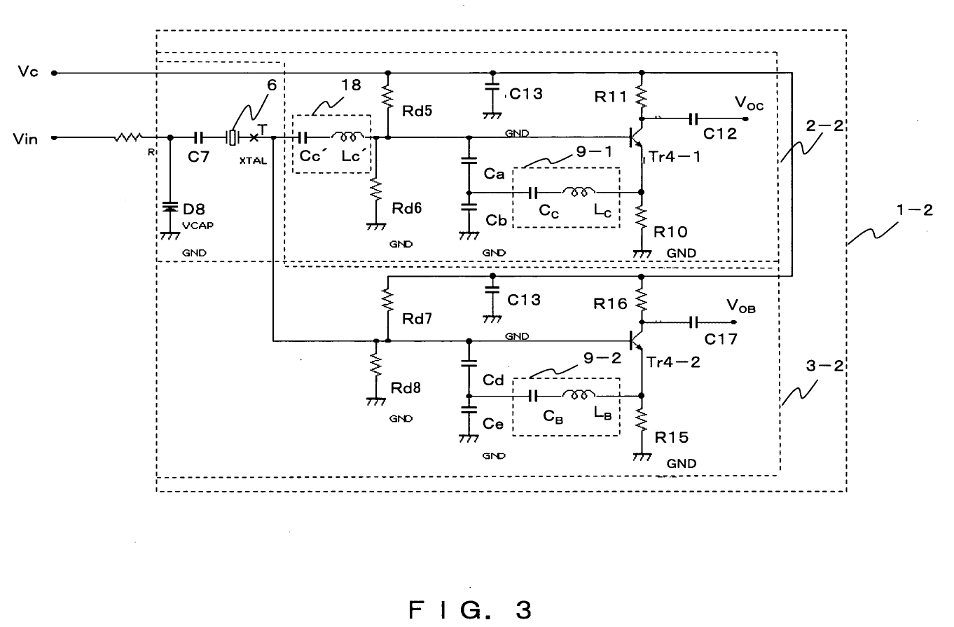

FIG. 3 is a diagram showing a dual mode quartz oscillation circuit 1-1 using an SC-cut quartz oscillator 6 (abbreviated as “quartz oscillator 6” hereinafter) in a modified Colpitts type oscillation circuit according to a first embodiment of the present invention.

The dual mode quartz oscillation circuit 1-1 comprises a C mode oscillation circuit part 2-2 and a B mode oscillation circuit part 3-2.

In the C mode oscillation circuit part 2-2, the base of a transistor Tr4-1 (used for an oscillation amplification) is connected to one end of an LC serial circuit 18 constituted by a capacitor Cc′ and an inductance Lc′, and the other end of the LC serial circuit 18 is connected to one end of a quartz oscillator 6. Here, the LC serial circuit 18 constitutes a band restriction unit. The other end of the quartz oscillator 6 is connected to one end of a capacitor C7 of which the other end is grounded by way of a variable-capacity diode D8. A serial circuit of division capacitors Ca and Cb is connected between the base and ground of the transistor Tr4-1, and a band restriction element, e.g., an LC serial circuit 9-1, is inserted between the connection point (i.e., the division point) between the division capacitors Ca and Cb and the emitter of the transistor Tr4-1. The emitter is connected to the ground by way of a resistor R10. The collector is configured so that a pull-up resistor R11 is connected to one end of a capacitor C12 and the other end thereof is made as an output terminal V_{OC}. Note that the Vc is the power source, Rd5, Rd6, Rd7 and Rd8 are transistor bias resistor, and the C13 is a bypass capacitor, in the showing of FIG. 3.

The transistor Tr4-1, division capacitors Ca and Cb, i.e., capacitive reactance, and the quartz oscillator 6, i.e., inductive reactance, constitute a Colpitts type oscillation circuit. An oscillation signal (i.e., an oscillation wave) of an oscillation frequency based on the resonance frequency of the quartz oscillator is output as a collector voltage, and the oscillation signal (i.e., the oscillation wave) is output to the output terminal V_{OC}. Furthermore, there is a modified Colpitts type oscillation circuit in which the LC serial circuit 9-1 is connected to the division point. The LC serial circuit 9-1 is for obtaining a narrow band negative resistance in the third overtone of the C mode.

The capacitance of the variable diode D8 is changed by giving thereto a reverse voltage and a load capacity against the quartz oscillator 6, thereby adjusting the oscillation frequency.

Then the B mode oscillation circuit part 3-2 is configured such that the base of an oscillation amplification-use transistor Tr4-2 is connected to one end of the quartz oscillator 6. The other end of the quartz oscillator 6 is connected to one end of the capacitor C7 and the other end thereof is grounded by way of the variable capacity diode D8. The serial circuit of division capacitors Cd and Ce is connected between the base and ground of the transistor Tr4-2, and a band restriction element, e.g., an LC serial circuit 9-2, is inserted between the connection point (the division point) between the division capacitors Cd and Ce and emitter. The emitter is grounded by way of the resistor R15. The collector is configured such that a pull-up resistor R16 is connected to one end of a capacitor C17 and the other end thereof is made as an output terminal V_{OB}.

The transistor Tr4-2, division capacitors Cd and Ce, i.e., capacitive reactance, and quartz oscillator 6, i.e., an inductive reactance, constitute a Colpitts type oscillation circuit. An oscillation signal (i.e., an oscillation wave) of an oscillation frequency based on the resonance frequency of the quartz oscillator 6 is output as a collector current, and the oscillation wave is output to the output terminal V_{OB}. Furthermore, it is a modified Colpitts type oscillation circuit with the LC serial circuit 9-2 being connected to the division point. The LC serial circuit 9-2 is for obtaining a narrow band negative resistance in the B mode fifth order overtone.

The dual mode quartz oscillation circuit 1-2 configured as described above is capable of implementing oscillations in both modes if a part indicated by a characteristic of a negative resistance is obtained in the oscillation frequency bands of the C mode and B mode. The resonance frequency (at approximately 10 MHz) of the C mode is the third overtone of the fundamental wave oscillation of the quartz oscillator 6, whereas the resonance frequency (at approximately 18.2 MHz) of the B mode is the fifth overtone.

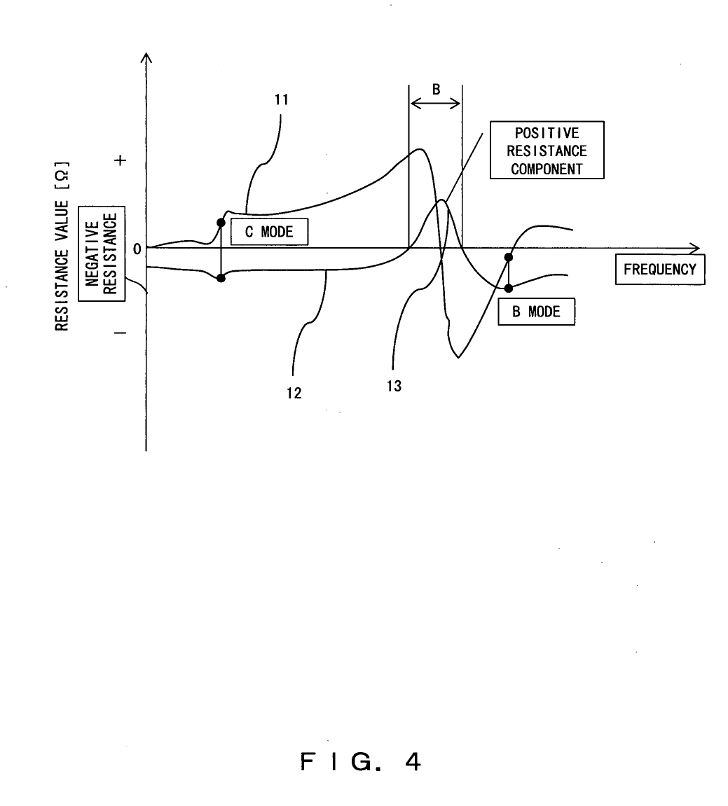

Here, FIG. 4 shows the negative resistance curve of the dual mode quartz oscillation circuit 1-2.

Referring to FIG. 4, negative resistance components appear respectively in the C mode oscillation frequency band and the B mode oscillation frequency band. That is, the negative resistance is a resistance of an actual part of (V₂−V₁)/i.

That is, FIG. 4 shows an imaginary part 11, and an actual part (i.e., a negative resistance curve) 12, of impedance of the first embodiment. These parts are actual measurement values of a practical circuit measured with a measurement instrument (i.e., an impedance analyzer).

Note that the measurement point is indicated by “T” in FIG. 3. The vertical axis indicates the resistance value [Ω] and the horizontal axis indicates the frequency [MHz].

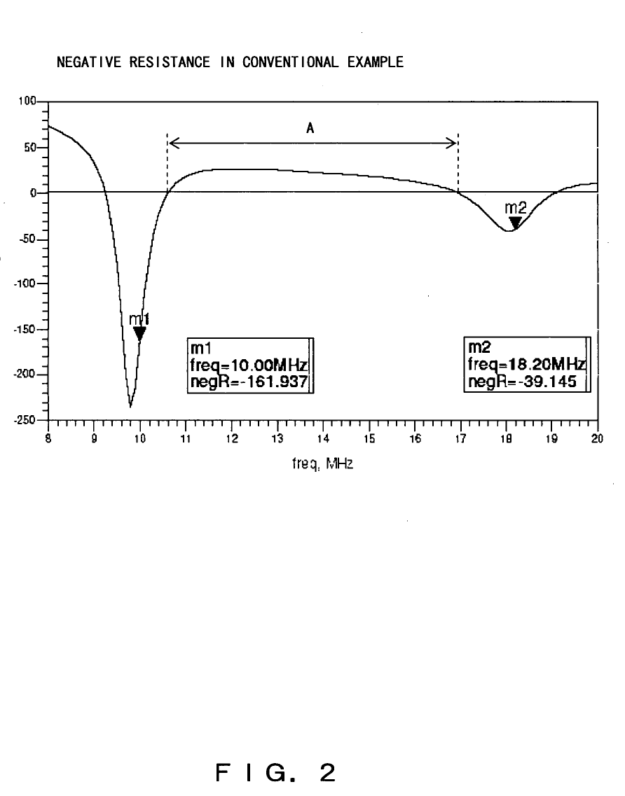

In the first embodiment, it has been validated the fact that an insertion of the LC serial circuit 18 as a band restriction element generates negative resistance components in the oscillation frequency bands of the B mode and C mode, respectively, and a positive resistance component appears between these negative resistance components and in the neighborhood of the oscillation frequency band of the B mode. This is shown as the mount part 13 (in the range of B) in the negative resistance curve 12. By virtue of this fact, the first embodiment is capable of performing a stable dual mode oscillation that has been impossible by the operation of the conventional example. That is, the conventional example has the characteristic of the positive resistance component as indicated by the range A shown in FIG. 2.

The first embodiment of the present invention performs a dual mode oscillation with the positive resistance component being generated as the mount part 13 (in the range of B) as shown in the negative resistance curve 12 shown in FIG. 4.

That is, the appearance of the mount part 13 (in the range of B) in the positive resistance component makes it possible to suppress an interference of the B mode oscillation and also implement a stable oscillation of B and C modes.

The following shows the result of an experiment of a negative resistance characteristic when varying capacitance values of respective LC serial circuits (9-1, 9-2 and 18) for the dual mode quartz oscillation circuit 2-2.

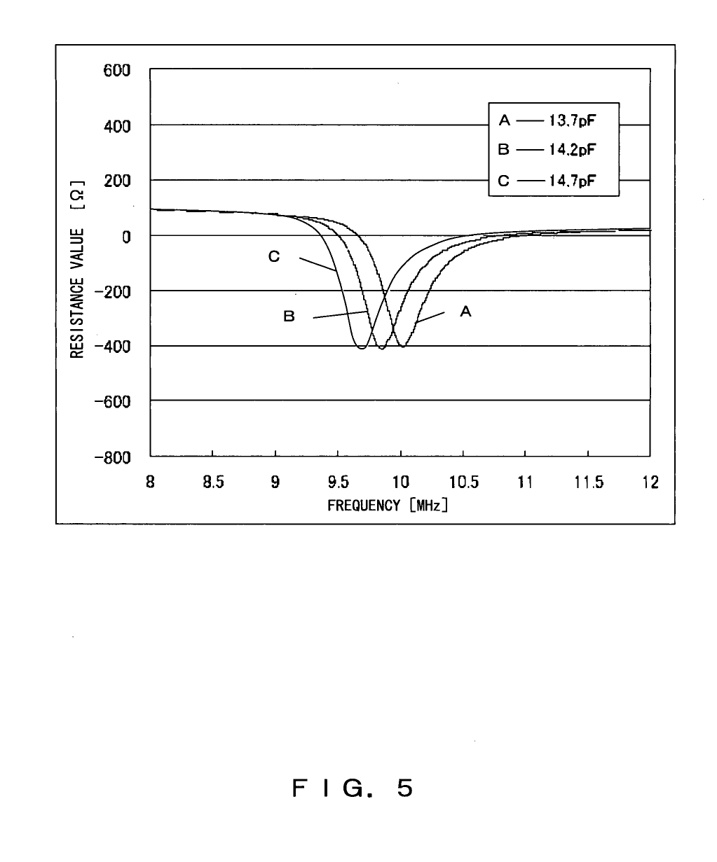

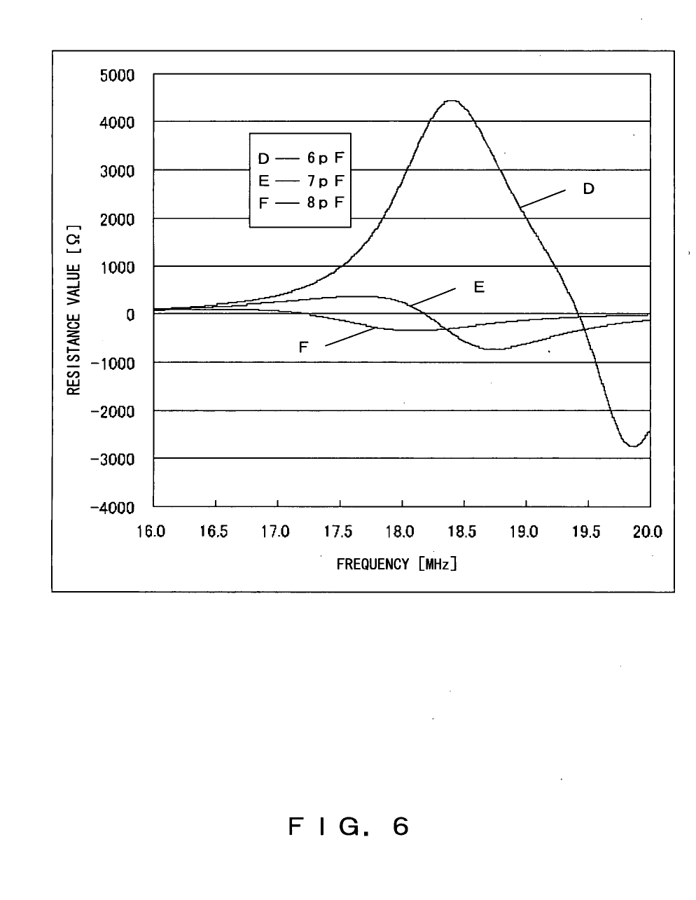

FIG. 5 is a diagram showing a simulation value of a negative resistance curve when varying a capacitance value of the Cc of the LC serial circuit 9-1 in the C mode oscillation circuit part 1-2 according to the first embodiment. (Note that the following FIGS. 6, 7 and 9 are also simulation values.) Here, the Lc is 10 μH. The vertical axis indicates a resistance value [Ω] and the horizontal axis indicates a frequency [MHz]. The curve A is for the capacitance value of Cc being 13.7 pF, the curve B is for the capacitance value of Cc being 14.2 pF and the curve C is for the capacitance value of Cc being 14.7 pF.

Based on FIG. 5, it has been validated through the comparison of the curves A, B and C that the peak of the negative resistance shifts slightly toward a lower frequency side with an increased capacitance. From this, it can be said that a frequency dependence of the negative resistance in the neighborhood of 10 MHz, that is the third overtone of the C mode, is low.

Meanwhile, FIG. 6 is a diagram showing a negative resistance curve when varying a capacitance value of the C_{B} of the LC serial circuit 9-2 in the B mode oscillation circuit part 3-2 according to a first embodiment. Note that the LB is 10 pH. The vertical axis indicates a resistance value [Ω] and the horizontal axis indicates a frequency [MHz]. The curve D is for the capacitance value of C_{B} being 6 pF, the curve E is for the capacitance value of C_{B} being 7 pF and the curve F is for the capacitance value of C_{B} being 8 pF.

Comparing the curves F with the curves D and E based on FIG. 6, one can comprehend the fact that the absolute value of the resistance component in the neighborhood of 18.2 MHz that is the fifth overtone of the B mode is very small. That is, a change of negative resistance against a frequency change of the B mode fifth overtone is small. This indicates that a peak of the absolute value of the negative resistance is smaller with the curve F, making a degree of amplification for the frequency small and making it hard to generate an abnormal oscillation phenomenon even if the spurious exists in the aforementioned frequency. Also, it can be said that a frequency dependence of the negative resistance in the neighborhood of 18.2 MHz, that is the fifth order overtone of the B mode is high because a degree of change is larger as compared to that of the negative resistance in the C mode.

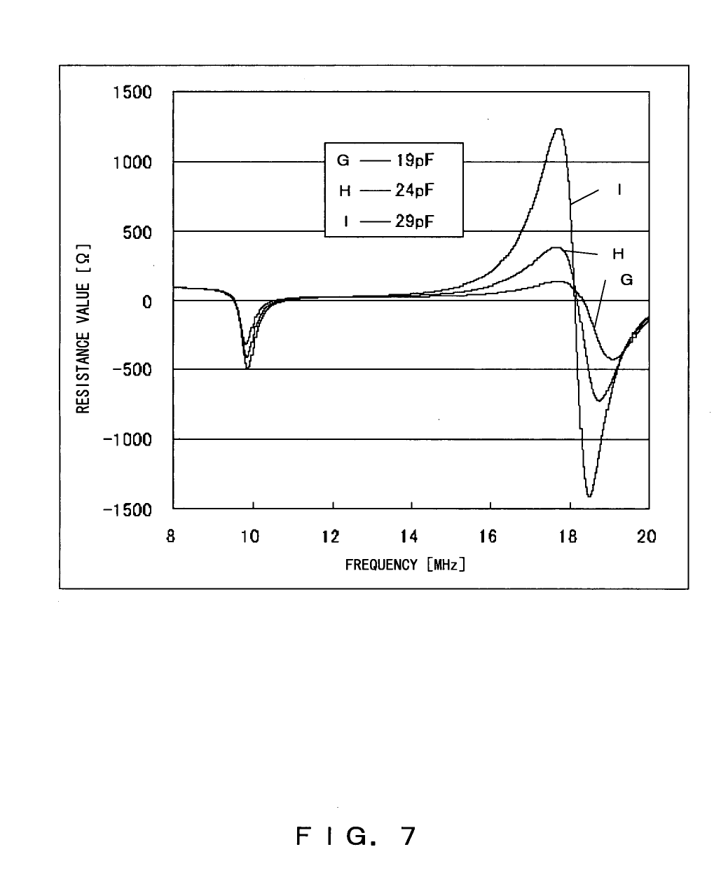

Furthermore, FIG. 7 is a diagram showing a negative resistance curve when varying a capacitance value of the Cc′ of the LC serial circuit 18 according to the first embodiment. Note that the Lc′ is 10 μH. The vertical axis indicates a resistance value [Ω] and the horizontal axis indicates a frequency [MHz]. The curve G is for the capacitance value of Cc′ being 19 pF, the curve H is for the capacitance value of Cc′ being 24 pF and the curve I is for the capacitance value of Cc′being 29 pF.

Comparing the curves G, H and I based on FIG. 7 has confirmed the fact that a peak of the negative resistance in the neighborhood of 10 MHz that is the third overtone of the C mode slightly shifts toward the high frequency side with an increase of the capacity. Also confirmed is the fact that the absolute value of the negative value of in the neighborhood of 18.2 MHz that is the fifth overtone of the B mode increases with the capacitance. Further confirmed is the fact that the absolute value of the positive resistance component in the neighborhood of 18.2 MHz that is in a relationship of the opposite position also increases. That is, confirmed is the fact that a change of the capacitance value of the Cc′ of the LC serial circuit 18 influences a change of the negative resistance in the oscillation circuit parts (2-2 and 3-2) of both modes. In other words, a peak value of the positive resistance prior to the B mode also increases as the C of the LC serial circuit increases from 19 to 24 to 29 pF, also increasing the amplitude of the negative resistance in the negative direction. As an example, the peak value of the positive resistance is a little smaller than 1 kilo ohm in the case of 29 pF (i.e., the curve I). Therefore, a pull-in phenomenon of overtones of the C and B modes does not occur, enabling an accomplishment of a highly stable dual mode oscillation.

### Second Embodiment

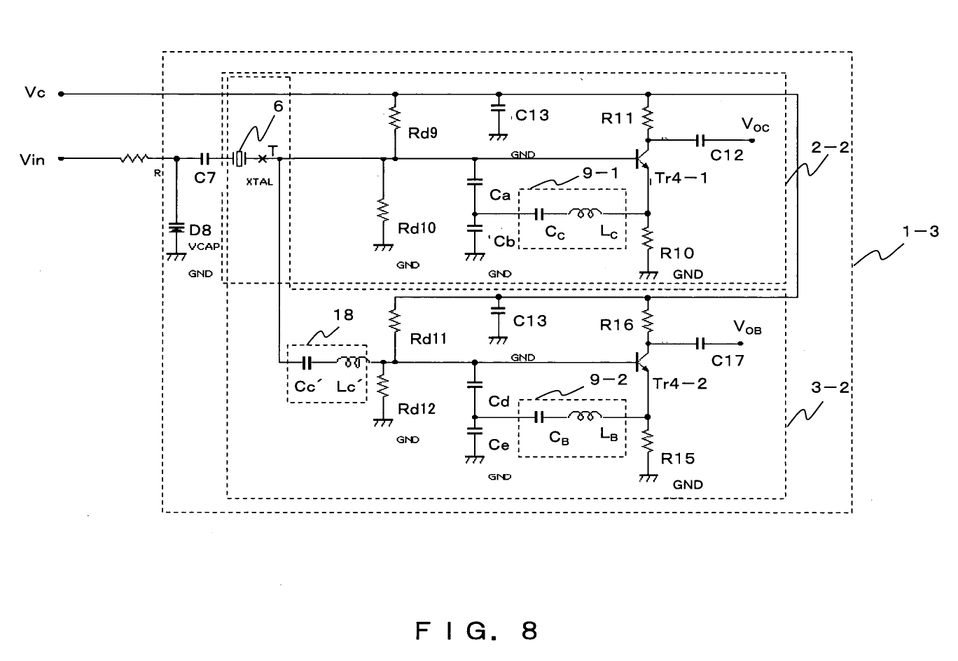

FIG. 8 is a diagram showing a dual mode quartz oscillation circuit 1-3 using an SC-cut quartz oscillator 6 in a modified Colpitts type oscillation circuit according to a second embodiment of the present invention. The characteristic of the present embodiment lies in inserting a band restriction element, e.g., the LC serial circuit 18, between one end of the quartz oscillator 6 and the base of the transistor Tr4-2 in the B mode oscillation circuit 3-2. The LC serial circuit 18 is for increasing an impedance in the B mode oscillation frequency.

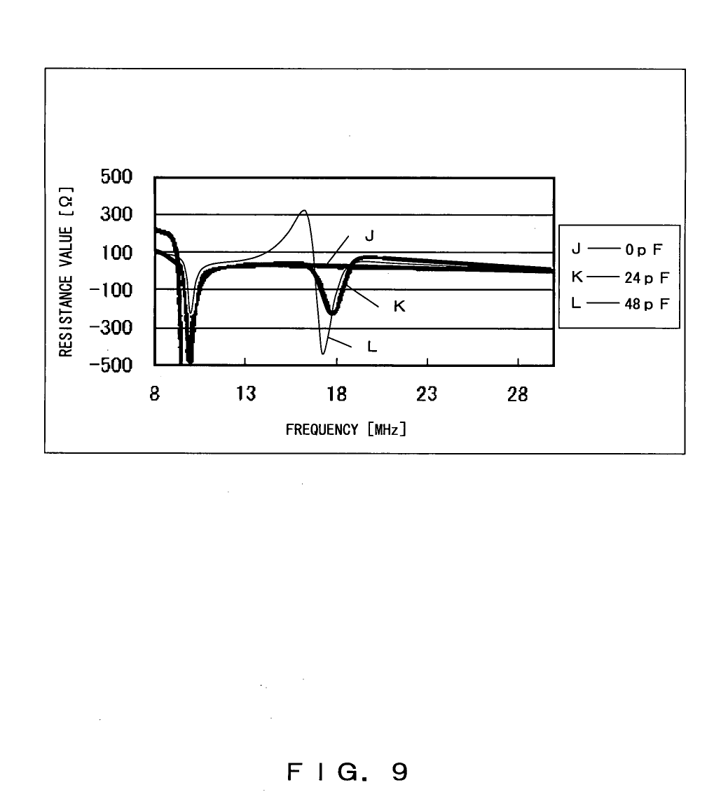

Also for the present embodiment, the appearance of a negative resistance of both modes and that of a positive resistance component in the neighborhood of the fifth overtone of the B mode has been confirmed as in the case of FIG. 7. FIG. 9 shows a negative resistance curve when varying the capacitance value of Cc′ in the above described event. Note that the measurement point is “T” shown in FIG. 8. The vertical axis indicates a resistance value [Ω] and the horizontal axis indicates a frequency [MHz]. The curve J is for the capacitance value of Cc′ being 0 pF, the curve K is for the capacitance value of Cc′ being 24 pF and the curve L is for the capacitance value of Cc′ being 48 pF. As for a change of the capacitance value, the fact has been confirmed that approximately the same change as the case of FIG. 7. Note that if the C of the LC serial circuit 18 is 0 pF, that is, a C does not exist, a dual mode oscillation does not occur as indicated by the curve J.

Therefore, the LC serial circuit 18 makes it possible to implement a stable oscillation of both modes of the C mode third overtone and B mode fifth overtone just by equipping in the oscillation circuit (2-2 or 3-2) of either mode.

It is also possible to perform a highly stable dual mode oscillation just by incorporating a combination of common impedance elements so as to make an amplitude on a positive resistance side in lieu of only a band restriction element (that is constituted by an LC circuit) as another embodiment of the present invention.

The preferred embodiments of the present invention have so far been described; the transistor, however, may use a field-effect transistor (FET) in lieu of being limited to the bipolar transistor. Also, the quartz oscillator may employ an IT-cut oscillator, in addition to the SC-cut. Furthermore, an Oven Controlled Crystal Oscillator (OCXO) that accommodates the quartz oscillator 6 and the peripheral circuit in a constant temperature bath may be adopted.

Note that the present invention may be configured in various ways possible within the scope thereof in lieu of being limited to the preferred embodiments described above.

What is claimed is:

1. A dual mode quartz oscillation circuit, comprising:
a first oscillation unit for oscillating a first mode overtone of a quartz oscillator;
a second oscillation unit for oscillating a second mode overtone of the quartz oscillator; and
a band restriction unit for inhibiting an interference of the overtones between the quartz oscillator and either one of the first or second oscillation unit.

2. The dual mode quartz oscillation circuit according to claim 1, wherein
said first mode is the third order overtone of a C mode, and said second mode is the fifth order overtone of a B mode.

3. The dual mode quartz oscillation circuit according to claim 1, wherein
said first and second oscillation units are modified Colpitts type oscillation circuit.

4. The dual mode quartz oscillation circuit according to claim 1, wherein
said first oscillation unit has a first division capacitor connected between the base and ground of a first transistor and comprises a first band restriction unit between the midpoint of the first division capacitor and the emitter of the first transistor, and
said second oscillation unit has a second division capacitor connected between the base and ground of a second transistor and comprises a second band restriction unit between the midpoint of the second division capacitor and the emitter of the second transistor.

5. The dual mode quartz oscillation circuit according to claim 4, wherein
said band restriction unit is constituted by a narrow band LC circuit.

6. The dual mode quartz oscillation circuit according to claim 1, wherein
said quartz oscillator is an SC-cut quartz oscillator.

7. The dual mode quartz oscillation circuit according to claim 1, wherein
said band restriction unit is constituted by a narrow band LC circuit.

8. The dual mode quartz oscillation circuit according to claim 1, wherein
the dual mode quartz oscillation circuit is an OCXO formed in the inside of a constant temperature bath.

9. The dual mode quartz oscillation circuit according to claim 2, wherein
the dual mode quartz oscillation circuit is an OCXO formed in the inside of a constant temperature bath.

10. The dual mode quartz oscillation circuit according to claim 3, wherein
the dual mode quartz oscillation circuit is an OCXO formed in the inside of a constant temperature bath.

11. The dual mode quartz oscillation circuit according to claim 4, wherein
the dual mode quartz oscillation circuit is an OCXO formed in the inside of a constant temperature bath.

12. The dual mode quartz oscillation circuit according to claim 5, wherein
the dual mode quartz oscillation circuit is an OCXO formed in the inside of a constant temperature bath.

13. The dual mode quartz oscillation circuit according to claim 6, wherein
the dual mode quartz oscillation circuit is an OCXO formed in the inside of a constant temperature bath.

14. A dual mode quartz oscillation circuit, comprising:
a first oscillation unit for oscillating a first mode overtone of a quartz oscillator;
a second oscillation unit for oscillating a second mode overtone of the quartz oscillator; and
an impedance element for inhibiting an interference of the overtone between either one of the first or second oscillation unit and the quartz oscillator and also making a dual mode oscillation performed.

15. The dual mode quartz oscillation circuit according to claim 14, wherein
at least one of said first and second oscillation units is modified Colpitts type oscillation circuit.
